(19) United States
(12) Patent Application Publication
(10) Pub. No.: US 2021/0367151 A1
(43) Pub. Date: Nov. 25, 2021

(54) MASK STRUCTURE FOR FORMING PIXEL UNIT ON SUBSTRATE AND METHOD FOR FORMING MASK

(71) Applicant: Wuhan China Star Optoelectronics Semiconductor Display Technology Co., Ltd., Wuhan (CN)

(72) Inventor: Xingchen DENG, Wuhan (CN)

(21) Appl. No.: 16/479,597

(22) PCT Filed: Jan. 3, 2019
(86) PCT No.: PCT/CN2019/070233

§ 371 Date: Jul. 21, 2019

(30) Foreign Application Priority Data
Oct. 16, 2018 (CN) 201811200154.X

(51) Int. Cl. H01L 51/00; H01L 51/56; C23C 14/04; C23C 14/24

(52) U.S. Cl. CPC H01L 51/0011; H01L 51/001; C23C 14/24; C23C 14/042; H01L 51/56

(57) ABSTRACT

The present disclosure provides a pixel arrangement structure and display panel. The pixel arrangement includes a plurality of pixel repeated combinations. Each of the pixel repeated combinations includes a plurality of pixel units. In the pixel repeated combinations, the plurality of pixel units share a sub-pixel and surround a center of the sub-pixel. By utilizing the present disclosure which makes pixels of the plurality of pixel units sharing one first sub-pixel, the numbers of the first sub-pixels in the pixel arrangement structure and the display panel are reduced, the resolution is enhanced, and fine metal mask (FMM) manufacture technology limitations can be overcome.

### FIELD OF INVENTION

The present disclosure relates to a field of mask structures, in particular to a mask structure for manufacturing an organic light-emitting diode.

### BACKGROUND OF INVENTION

Display quality and power efficiency requirements are higher with development of smart terminals. Organic light-emitting diodes (OLEDs) play an important role in development of display due to advantages such as bright color, a high contrast ratio, low power consumption, good flexibility etc. OLED displays are applied in wider areas with growth of manufacturing technology.

The most distinct difference between OLED display and general display is the manufacturing process utilizing vacuum vapor deposition technology. In a deposition process, a metal mask will be precisely fastened on a glass substrate so that organic light-emitting materials of three colors, red (R), green (G), and blue (B), are vapor deposited on the substrate through an opening on the metal mask. OLED display panels illuminate RGB lights through self-light emitting organic materials to compose different colors.

Full screen display panels become one of main trends of smart terminals. As shown in FIG. 1, a smart terminal 10 includes a display panel 12 which has a pixel area 14 and a non-pixel area 16. The pixel area 14 has RGB OLED for display images. The non-pixel area does not possess OLED but possesses components, such as front camera lens, a speaker, a light sensor, fill light, etc., which are disposed on the display panel 12.

A method to manufacture the display panel as shown in FIG. 1 is to utilize a notch mask structure 20 as shown in FIG. 2. The notch mask structure 20 includes a mask frame 200, a plurality of covers 220, a plurality of howlings 240, and a plurality of metal sheets 260. The plurality of covers 220 are disposed on the mask frame 200 in a longitudinally parallel and equidistant manner for shielding the glass substrate (not shown) during an exposure process so that the organic light-emitting materials are not vapor deposited on the area sheltered by the covers 220. The plurality of howlings 240 are disposed on the covers 220 in parallel and equidistant directions. The howlings 240 are utilized to support the metal sheets 260. The howlings 240 also perform as shelter so that the organic light-emitting materials are not vapor-deposited on the area covered by the howlings 240. The metal sheets 260 are netted above the howlings 240. The howlings 240 is utilized to withstand the tension of the metal sheets 260. Each of the metal sheets 260 has a plurality of pixel forming areas 262. The longitudinal covers 220 and the lateral howlings 240 are interleaved to form a plurality of panel pixel areas 264. Shapes of the panel pixel areas 264 correspond to shapes of the pixel forming areas 262. The organic light emitting material shapes the display panel according to the shapes formed by the covers 220, the howlings 240, the pixel formation area 262, and the panel pixel area 264. Taking the notch mask structure shown in FIG. 2 as an example. There are seven covers 220, five howlings 240, and eight metal sheets 260 thus there are pixel areas 264 arranged in eight columns and six rows. Therefore, in one manufacturing process, 48 (8*6) display panels can be formed.

By utilizing the notch mask structure 20 illustrated in FIG. 2, there are two existing methods to form the display panel 12 as shown in FIG. 1. A first method is to change the shape of the cover 220. A shape corresponding to the non-pixel area 16 is designed on the cover 220 so that the shape of the panel pixel area 264 is correspondingly changed. The organic light-emitting materials are only deposited on the non-covered area. A second method is to change the design of the metal sheet 260 to make the shape of the pixel forming area 262 to correspond to the shape of the pixel area 14 on the display panel 12, thus light-emitting materials are only deposited in the pixel forming area 262. Therefore, the organic light-emitting materials of the pixel area 14 are formed on the glass substrate as the shape of the pixel forming area 262 even a shape of the panel pixel area 264 is still a rectangle. However, the metal sheets 260 are parts of a fine metal mask (FMM), which is costly to change and difficult to accurately represent the desired shape.

If the shape of the mask strip 220 is changed, the tension applied to the mask frame 200 and the howlings 240 may also change. Uneven tension may cause the pixel position accuracy (PPA) of the pixel to decrease and cause color mixture or color to shift. The cost of changing the design of the metal sheet is too high and the shape accuracy is too low. In addition, the thinner the cover and the howlings are, the less the tension they have. The display panel cannot be mass-produced if the tensions of the cover and the howlings are not high enough. On the other hand, if the cover and the howlings are too thick, shadows are formed on the glass substrate which causes an error in pixel evaporation.

Hence, a mask structure, which does not require changing the metal sheet, does not cause uneven tension between the mask frame and the howlings, and does reduce the shadow area, is required for manufacturing a full screen OLED display panel.

### SUMMARY OF INVENTION

The present disclosure provides mask structure for disposing pixel units on a substrate including a mask frame, a plurality of smooth covers, a plurality of protruding covers, a plurality of support bars, and a plurality of fine metal mask. The plurality of smooth covers is vertically disposed on the mask frame and being parallel to each other. The plurality of protruding covers is vertically disposed on the mask frame and being parallel to the plurality of smooth covers and including a plurality of protruding units. Each of the protruding covers has same shape and has a same number of a number of the protruding units. After forming the smooth covers and the protruding covers in a same process, coating and etching the protruding covers to form the protruding units. The plurality of support bars is horizontally disposed on the smooth covers and the protruding covers. Each of the support bars is parallel to each other. The support bars perpendicularly cross with the smooth covers and the protruding covers to form a plurality of pixel blocks. Shapes of each column of the pixel blocks are the same. Two of adjacent rows of pixel blocks are symmetric to a corresponding smooth cover or two of adjacent rows of pixel blocks are symmetric to a corresponding protruding cover. The plurality of fine metal masks is disposed on the support bars and including a plurality of pixel forming area. An area of the pixel forming area is larger than an area of the pixel block.

The present disclosure provides mask structure for disposing pixel units on a substrate including a mask frame, a plurality of smooth covers, a plurality of protruding covers, a plurality of support bars, and a plurality of metal bars. The plurality of smooth covers is vertically disposed on the mask frame and being parallel to each other. The plurality of protruding covers is vertically disposed on the mask frame and being parallel to the plurality of smooth covers and including a plurality of protruding units. Each of the protruding covers has same shape and has a same number of a number of the protruding units. After forming the smooth covers and the protruding covers in a same process, coating and etching the protruding covers to form the protruding units. The plurality of support bars is horizontally disposed on the smooth covers and the protruding covers. Each of the support bars is parallel to each other. The support bars perpendicularly cross with the smooth covers and the protruding covers to form a plurality of pixel blocks. The plurality of metal bars is disposed on the support bars and including a plurality of pixel forming area, wherein an area of the pixel forming area is larger than an area of the pixel block.

In the mask structure of the present disclosure, structures of the protruding covers and the smooth covers are the same after forming the smooth covers and the protruding covers by coating, exposing, and etching process, wherein the protruding units are formed after coating and etching the protruding covers.

In the mask structure of the present disclosure, after forming the smooth covers and the protruding covers in a same process, coating and etching the protruding covers to form the protruding units.

In the mask structure of the present disclosure, shapes of each column of the pixel blocks are the same and two of adjacent rows of pixel blocks are symmetric to a corresponding smooth cover or two of adjacent rows of pixel blocks are symmetric to a corresponding protruding cover.

In the mask structure of the present disclosure, a cross-section of the support bar is trapezoid.

In the mask structure of the present disclosure, the metal bars are fine metal masks.

In the mask structure of the present disclosure,

The present disclosure provides a method for forming a mask utilized to forming pixel units on a substrate including: coating a first block material and forming a plurality of smooth covers by exposing and etching the first block material; coating and etching parts of the smooth covers to from a plurality of protruding bars; coating a second block material and forming a plurality of support bars by exposing and etching the second block material; parallel interlacing the smooth covers and the protruding covers vertically on a mask frame; parallel disposing the support bars on the smooth covers and the protruding covers, wherein the support bars cross with the smooth covers and the protruding covers to form a plurality of pixel blocks; disposing metal bars including a plurality of pixel form areas on the support bars.

In the method for forming a mask of the present disclosure, after forming the smooth covers and the protruding covers in a same process, coating and etching the protruding covers to form the protruding units

In the method of the present disclosure, shapes of each column of the pixel blocks are the same, two of adjacent rows of pixel blocks are symmetric to a corresponding smooth cover or two of adjacent rows of pixel blocks are symmetric to a corresponding protruding cover.

In the method for forming a mask of the present disclosure, a cross-section of the support bar is trapezoid.

In the method for forming a mask of the present disclosure, the metal bars are fine metal masks.

The advantages of the present disclosure is changing the design of the pixel forming area on the metal sheet is not necessary by using the mask structure of the disclosure. The present disclosure changes the design of the covers and the support bars which interacts the pixel areas having a notch. Therefore, pixel area of a panel with a notch is formed because the organic light-emitting materials cannot be formed outside the pixel area of the panel. The design and the manufacturing process of the mask structure of the present disclosure are simple. The color shift and color mixture of the pixel area formed by the mask structure of the present disclosure are reduced. Hence the display quality is improved and the manufacturing cost is reduced.

### DESCRIPTION OF DRAWINGS

FIG. 1 illustrates a schematic structure of a full screen display panel;

FIG. 2 illustrates an existing notch mask structure;

FIG. 3 illustrates a schematic of a display panel of the present disclosure;

FIG. 4 illustrates a flow chart for forming smooth covers and protruding covers of the present disclosure;

FIG. 5 illustrates a schematic structure of the smooth covers, the protruding covers, and a mask frame of the present disclosure;

FIG. 6 illustrates a schematic structure of supporting bars;

FIG. 7 illustrates a schematic structure of metal bars of the mask structure of the present disclosure.

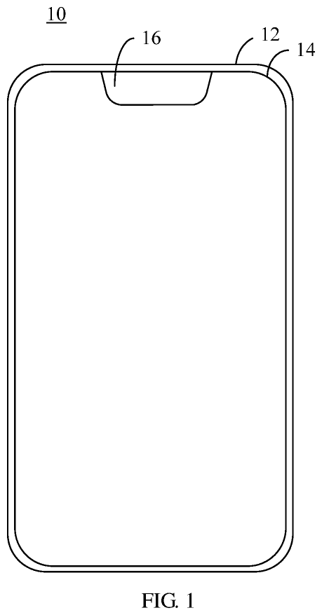

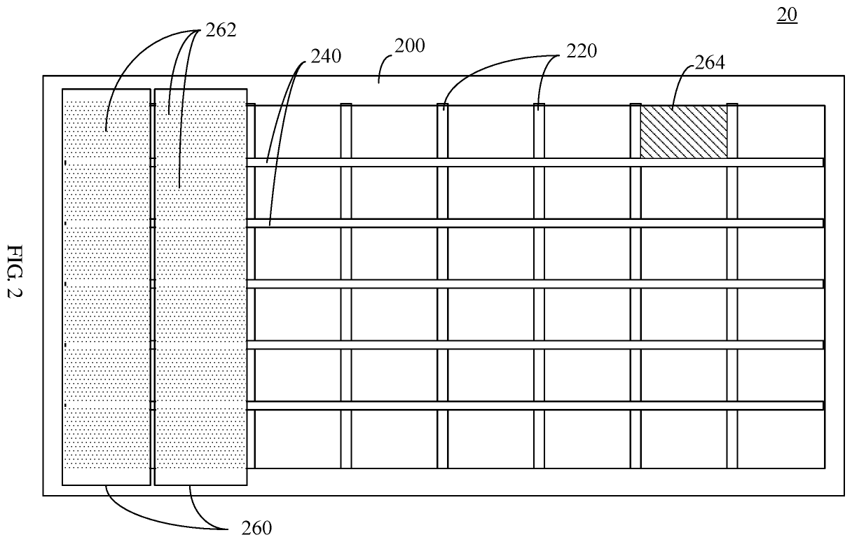

### DETAILED DESCRIPTION OF PREFERRED EMBODIMENTS

The display panel and the display device provided by the present disclosure will be described in detail below with reference to the accompanying drawings. The longitudinal, lateral, upper, lower, left, right, front, and rear aspects of the detailed description are merely for convenience of describing the relative relationship between the components rather than limitations of embodiments of the present disclosure. It is apparent that the described embodiments only exemplify a part of the embodiments of the disclosure. All other embodiments which can be obtained by a person of ordinary skill in the art based on the embodiments of the present disclosure without creative efforts fall within the scope of the present disclosure.

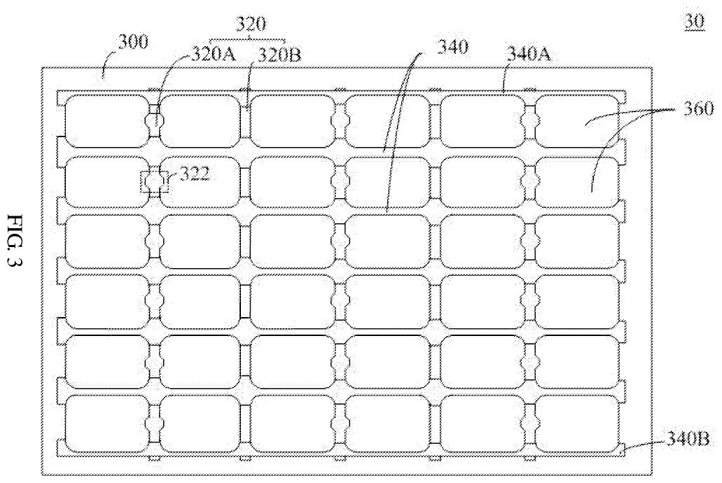

FIG. 3 illustrates a mask structure 30 according of the present disclosure. The mask structure 30 is utilized to adhere to a glass substrate of a display panel (not shown) in manufacturing processes of organic light-emitting diodes (OLEDs). An organic light-emitting material will be formed in areas which are not covered by the mask structure 30 corresponding to a shape of the mask structure 30.

The mask structure 30 of the present invention comprises a metal frame 300, a plurality of covers 320, and a plurality of supporting bars (howlings) 340. The plurality of covers 320 are arranged in parallel in the longitudinal direction, and the plurality of supporting bars 340 are arranged in parallel in the horizontal direction. The covers 320 include protruding covers 320A and smooth covers 320B. The protruding cover 320A has a protruding unit 322. The smooth cover 320B is a straight strip structure without a protruding unit. The protruding cover 320A and the smooth cover 320B are spaced by each other, that is, covers are arranged in order as 320A-320B-320A-320B. The covers 320 are formed first, and then protruding units 322 are formed on the cover 320A to form protruding cover 320A by performing coating and etching processes. Thus, the protruding covers 320A are covers having the protruding unit 322 and the smooth covers 320B are covers having no protruding units 322. After the covers 320A and the smooth covers 320B are formed, the supporting bars 340 are placed on the covers 320 in a laterally parallel direction, and both sides of the supporting bar 340 are connected to the metal frame 300. In addition, the supporting bar 340 contains partly supporting bars 340A and 340B. Because partly supporting bars 340A and 340B are disposed on the metal frame 300, half of the area of the partly supporting bars 340A and 340B cover on the metal frame 300, so only half area of the support bar 340 is required to forming the partly supporting bars 340A and 340B so that the material cost of the supporting bar 340 can be saved. In the meanwhile, the mask structure 30 can be maintained symmetrically to ensure that the tension of the mask structure 30 is evenly stressed. However, this embodiment is only an example. For the convenience of the process, the supporting bar 340 disposed on the metal frame may also have the same structure as the other supporting bars 340.

The mask structure 30 shown in FIG. 3 has five covers 320, three of which are the protruding cover 320A and two of which are the smooth cover 320B, seven supporting bars 340, and two partly supporting bars 340A and 340B. The covers 320 and the supporting bars 340 are intersected to form a plurality of panel pixel areas 360. Taking the structure of FIG. 3 as an example. The five cover 320, the seven supporting bars 340, and the metal frame 300 form six-row and six-column panel pixel areas 360. The total number of the panel pixel areas 360 is 36 panel pixel areas 360, thus 36 pixel areas of display panels can be made in one manufacturing process. By adjusting the interval space and the number of covers and support bars, the sizes and of the pixel area of panels can be set and the manufacturing number of the pixel area of panels can meet manufacturing requirement in one manufacturing process. Preferably, the column number of the pixel areas of panels generated by one manufacturing process is even so that the tension stress and symmetry can be maintained.

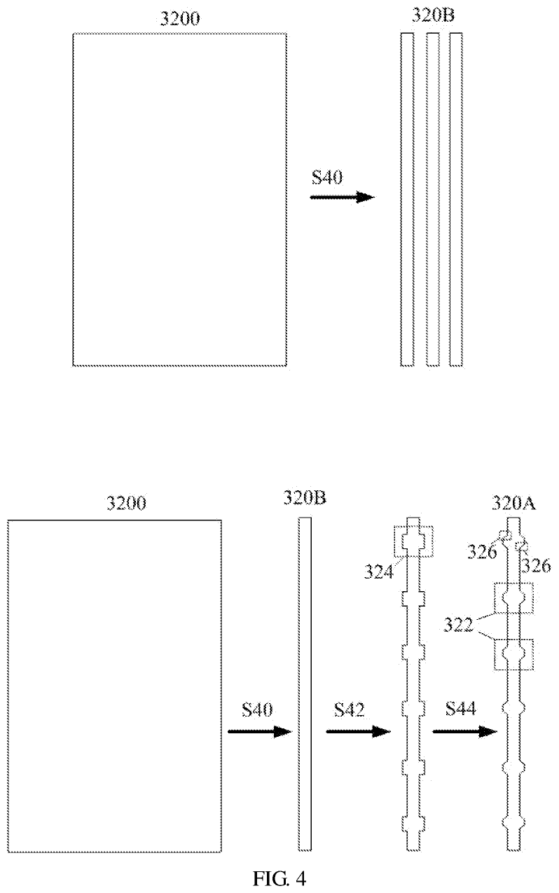

Please refer to FIG. 4 to FIG. 6 for the detailed manufacturing processes of the mask structure.

FIG. 4 is a flow chart of forming a protruding cover 320A and a smooth cover 320B. As shown in FIG. 4, first, step S40 is forming a light-shielding material 3200 into smooth covers 320B. Step S40 includes manufacturing process technologies, such as coating, exposure, and etching etc.

The protruding cover 320A is first formed as the same structure as the smooth cover 320B by the manufacturing process of coating, exposing, and etching the light-shielding material 3200 in step S40, then step S42 is performed to form a first protruding unit 324 through a coating process and step S44 is performed to form a corner structure 326 by an etching process. Accordingly, the protruding units 322 can be formed on the straight-strip shaped covers 320 to form the protruding covers 320A. However, the above-mention step is merely an example instead of a limitation of the manufacturing processes and steps to form protruding cover 320A. For example, changing a shape of a mask utilized in exposure process and changing the etching portion to form a shape of the protruding unit 322 on the basis of the original manufacturing processes, coating, exposure, etching, and stripping, for forming the smooth cover 320B, so that the exposed covers have the first protruding units 324. That is, by changing the original exposure and etching processes, the protruding covers 320A having the protruding units 322 can also be formed.

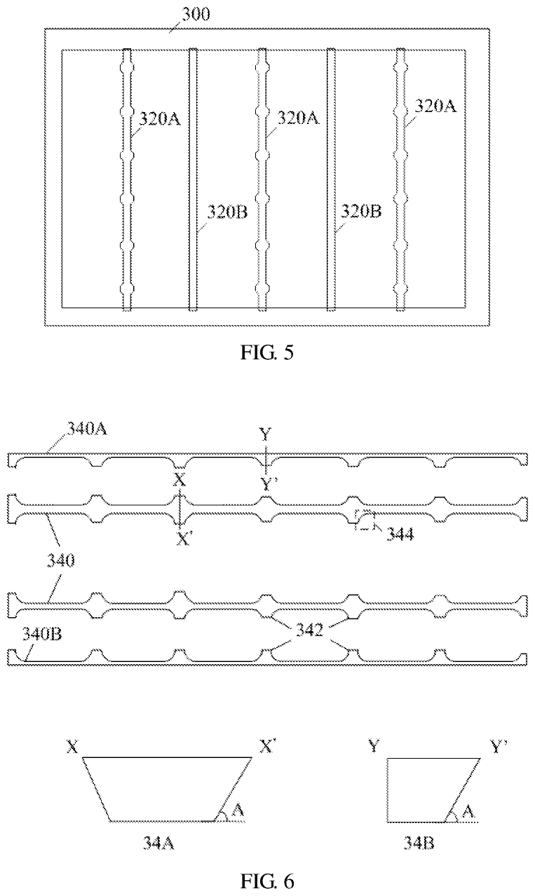

FIG. 5 is a schematic structure of the metal frame 300 and the cover 320. The cover 320 is fixed on the metal frame 300 by a connecting manner such as soldering. The arrangement and the number of the covers 320 in FIG. 5 are only an embodiment. The arrangement width and the number of the covers 320 on the metal frame 300 can be adjusted according to elements such as the pixel and the size of the display panel. The mask structure 30 is attached to the glass substrate, so that the organic light-emitting materials are not formed in the area covered by the covers 320 and not formed in the area covered by the protruding units 322 of the supporting bars 320A. Therefore, a notch is formed in the pixel area of the display panel.

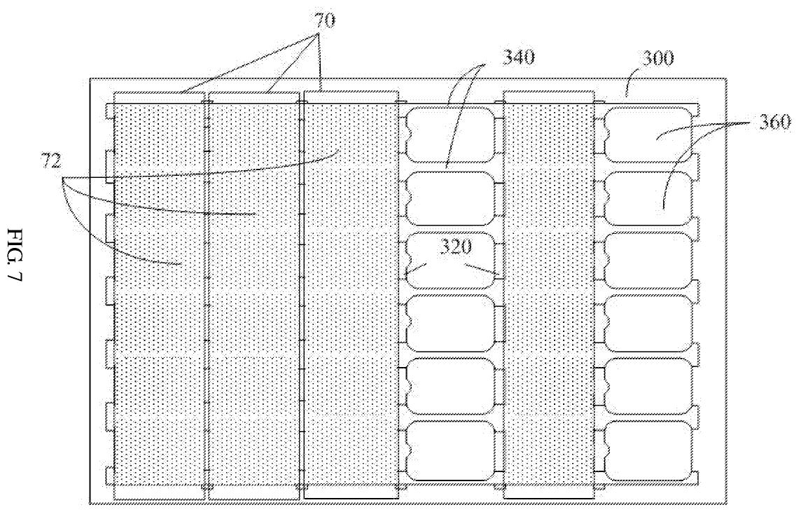

FIG. 6 illustrates the structure of the supporting bars 340. The structure of the supporting bar 340 and the partly supporting bar 340A and 340B are shown in FIG. 6. The supporting bar 340 has a supporting protruding unit 342. The position of the supporting protruding unit 342 corresponds to the covers 320. The structure of the supporting protruding units 342 can enhance the stability of the supporting bars 340 disposing on the covers 320. The shape and width of the supporting protruding units 342 also correspond to covers 320. The supporting bars 340 further include fillets 344. Shapes of the fillets 344 correspond to the desired shape of the pixel area of the display panel. Supporting bars 340 are formed by the similar manufacturing processes as the covers 320 which include coating, exposure, etching, etc. For the steps, please refer to the manufacturing processes of the cover 320, the steps for forming the supporting bars 340 will not be repeated.

Please refer to FIG. 6. FIG. 6 illustrates a cross-sectional structure 34A which is sectioned along the X-X′ direction of the supporting bar 340 and illustrates a cross-sectional 34B which is sectioned along the Y-Y′ direction of the supporting bar 340A. The partly supporting bar 340B has a symmetrical cross-sectional structure as the cross-sectional structure 34B, therefore, the cross-sectional structure of the partly supporting bar 340B and will not be described again. According to the cross-sectional structure of the supporting bars shown in FIG. 6, an angle A in the cross-sectional structure is about 50 to 60 degrees. This structure can reduce a projected area generated by light transmission to the glass substrate via the supporting bar 340 during the exposure process. Therefore, shadow effect is reduced and the position of the exposure process becomes more precise.

The mask structure 30 as shown in FIG. 3 is obtained after disposing the supporting bars 340 on the covers 320. The covers 320 and the supporting bars 340 formed by the above-mentioned steps crisscross to form the panel pixel areas 360 which having a pixel area with a notch.

FIG. 7 illustrates metal bars 70 disposing on the mask structure 30. The metal bars 70 have a plurality of pixel forming areas 72. The organic light emitting materials are formed in the pixel forming area 72. Please refer to FIG. 3 together. Because shapes of the panel pixel area 360 of the mask structure 30 are the shape of the pixel area of the display panel, even the range of the pixel forming area 72 is larger than the panel pixel area 360, the portion beyond the panel pixel area 360 is not exposed due to the shelter of the panel pixel area 360 formed by the covers 320 and the supporting bars 340. As a result, the metal bars 70 having the pixel forming area 72 without notches can be directly applied to the mask structure 30 of the present disclosure. That is, the rectangular pixel forming area 262 of the metal bar 260 can be directly applied to the mask structure 30 of the present disclosure to form pixel areas having a notch on display panels without changing the structure of the pixel forming area of the metal bar.

The mask structure of the present disclosure achieves the shelter effect by changing the shape of the covers and the supporting bars to manufacture a display panel having a pixel area with a notch for producing a full-screen display panel. The outcome structure has very high precision because the covers and the supporting bars are formed by manufacturing processes, such as coating, exposure, etching, etc., which are extremely mature manufacturing processes so that the shapes of the pixel area of the panel can be formed very precisely. The metal bar is made of a fine metal mask. The cost of the changing the design of the fine metal mask is higher and the precision is not as good as the mature manufacturing processes technology, such as coating, exposure, and etching. In addition, forming notches on the fine metal mask is prone to breakage. Therefore, in comparison with changing the design of the metal bar, the present disclosure reduces the difficulty of forming a notch on pixel areas by changing the design of the covers and the supporting bars. In the meanwhile, the accuracy of the shape of the pixel area is improved and manufacturing cost is reduced.

In addition, the mask structure of the present disclosure, including metal frame, covers, or supporting bars, are symmetric. As a result, the tension is even, and the thickness and position accuracy of the organic light-emitting materials are not affected by the changed shape of covers and supporting bars. Besides, the cross-section of the supporting bar is a trapezoidal structure which can reduce the shadow formed on the glass substrate during the exposure process and improve the accuracy of the arrangement of the organic light-emitting materials.

The advantages of the mask structure of the present invention are not only low cost, but also precise pixel area shapes, uniform arranged thickness of the organic light-emitting materials, high positional accuracy, less shadow effect, and lower color mixture and color shift. Therefore, the display quality is improved.

To conclude, embodiments disclosed above are preferable embodiments rather than limitation of the present disclosure. Any changes and modifications can be completed by a skilled person in the art on the basis of the concept and the scope of the present disclosure. Therefore, the protected scope should base on the scope defined by claims in the present disclosure.

What we claim is:

1. A mask structure for disposing pixel units on a substrate, comprising:
a mask frame;
a plurality of smooth covers vertically disposed on the mask frame and parallel to each other;
a plurality of protruding covers vertically disposed on the mask frame and parallel to the plurality of smooth covers and comprising a plurality of protruding units, wherein each of the protruding covers has a same shape and has a same number of a number of the protruding units, wherein after forming the smooth covers and the protruding covers in a same process, coating and etching the protruding covers to form the protruding units;
a plurality of support bars horizontally disposed on the smooth covers and the protruding covers, each of the support bars are parallel to each other, wherein the support bars perpendicularly cross with the smooth covers and the protruding covers to form a plurality of pixel blocks, wherein shapes of each column of the pixel blocks are the same, two of adjacent rows of pixel blocks are symmetric to a corresponding smooth cover or two of adjacent rows of pixel blocks are symmetric to a corresponding protruding cover; and
a plurality of fine metal masks disposed on the support bars and comprising a plurality of pixel forming areas, wherein an area of the pixel forming area is larger than an area of the pixel block.

2. A mask structure for disposing pixel units on a substrate, comprising,
a mask frame;
a plurality of smooth covers vertically disposed on the mask frame and being parallel to each other;
a plurality of protruding covers vertically disposed on the mask frame and being parallel to the plurality of smooth covers and comprising a plurality of protruding units, wherein each of the protruding covers has a same shape and has same number of a number of the protruding units;
a plurality of support bars horizontally disposed on the smooth covers and the protruding covers, each of the support bars are parallel to each other, wherein the support bars perpendicularly cross with the smooth covers and the protruding covers to form a plurality of pixel blocks; and
a plurality of metal bars disposed on the support bars and comprising a plurality of pixel forming areas, wherein an area of the pixel forming area is larger than an area of the pixel block.

3. The mask structure according to claim 2, wherein structures of the protruding covers and the smooth covers are the same after forming the smooth covers and the protruding covers by coating, exposing, and etching processes, wherein the protruding units are formed after coating and etching the protruding covers.

4. The mask structure according to claim 2, after forming the smooth covers and the protruding covers in a same process, coating and etching the protruding covers to form the protruding units.

5. The mask structure according to claim 2, wherein shapes of each column of the pixel blocks are the same, two of adjacent rows of pixel blocks are symmetric to a corresponding smooth cover or two of adjacent rows of pixel blocks are symmetric to a corresponding protruding cover.

6. The mask structure according to claim 2, wherein a cross-section of the support bar a trapezoid.

7. The mask structure according to claim 2, wherein the metal bars are fine metal masks.

8. A method for forming a mask utilized to forming pixel units on a substrate, comprising:
coating a first block material and forming a plurality of smooth covers by exposing and etching the first block material;
coating and etching parts of the smooth covers to form a plurality of protruding bars;
coating a second block material and forming a plurality of support bars by exposing and etching the second block material;
parallel interlacing the smooth covers and the protruding covers vertically on a mask frame;
parallel disposing the support bars on the smooth covers and the protruding covers, wherein the support bars cross with the smooth covers and the protruding covers to form a plurality of pixel blocks; and
disposing metal bars comprising a plurality of pixel form areas on the support bars.

9. The method for forming the mask according to claim 8, wherein after forming the smooth covers and the protruding covers in a same process, coating and etching the protruding covers to form protruding units.

10. The method for forming the mask according to claim 8, wherein shapes of each column of the pixel blocks are the same, two of adjacent rows of pixel blocks are symmetric to a corresponding smooth cover or two of adjacent rows of pixel blocks are symmetric to a corresponding protruding cover.

11. The method for forming the mask according to claim 8, wherein a cross-section of the support bar is trapezoid.

12. The method for forming the mask according to claim 8, wherein the metal bars are fine metal masks.
